(19) United States
(12) Patent Application Publication
(10) Pub. No.: US 2018/0110305 A1
(43) Pub. Date: Apr. 26, 2018

(54) ELECTROMAGNETIC WAVE BLOCKING STORAGE ARTICLE HAVING INFORMATION PROTECTION FUNCTION

(71) Applicants: Nam Sic KIM, Daegu (KR); Hyun Yu NAM, Daegu (KR)

(72) Inventors: Nam Sic KIM, Daegu (KR); Hyun Yu NAM, Daegu (KR)

(21) Appl. No.: 15/562,884

(22) PCT Filed: Apr. 4, 2016
(86) PCT No.: PCT/KR2016/003448

§ 371 Date: Sep. 28, 2017

(30) Foreign Application Priority Data
Apr. 3, 2015 (KR) 10-2015-0047599

(51) Int. Cl. A45C 11/18; A45C 1/06; H05K 9/00

(52) U.S. Cl. CPC A45C 11/182; A45C 2011/186; H05K 9/0083; A45C 1/06

(57) ABSTRACT

The present invention provides an electromagnetic wave blocking storage article. The electromagnetic wave blocking storage article includes: a wallet body part configured such that a storage pocket is formed therein; and an electromagnetic wave blocking part configured to be formed in a plate shape, to be embedded in the storage body part, and to block electromagnetic waves transferred from the outside of the storage body part.

### TECHNICAL FIELD

The present invention relates generally to an electromagnetic wave blocking storage article having an information protection function, and more specifically to an electromagnetic wave blocking storage article having an information protection function, in which an electromagnetic shielding and absorbing material made of polymer or a composite thereof is used as the outer material (shape maintaining material) of the article, thereby making it possible to prevent the leakage of information stored in accommodated related items, such as an IC card, an RF chip, a smart key, and other IT devices, or to protect the devices.

### BACKGROUND ART

Generally, most cards including credit cards are each provided with an IC or chip in which personal information is embedded. A smart key, etc. are each provided with a separate signal generator.

In general, a user carries a card, a key, or the like, in which information has been embedded, as described above, in his or her pocket.

However, when electromagnetic waves generated by an external device are transferred to a card, a key, or the like accommodated in a wallet of a user while the user is not being aware of the fact,

there frequently occurs the problem in which information embedded in the corresponding card, the corresponding key or the like is leaked to the outside via the electromagnetic waves generated by the external electronic device without separate manipulation.

Accordingly, the reality is that such problems cause significant inconvenience and anxiety for people of today who frequently use IT products.

In particular, in recent years, in developed countries including the U.S., information is leaked from cards, keys and/or the like, accommodated in wallets possessed by users, in a non-contact manner by using the principle of an RFID reader and illegitimately used in crime, which has become a huge social problem.

As a prior art document related to the present invention, there is Korean Utility Model Registration Application Publication No. 20-0447574 (Jan. 26, 2010).

### DISCLOSURE

### Technical Problem

An object of the present invention is to provide an electromagnetic wave blocking storage article having an information protection function, in which an electromagnetic wave blocking (shielding & absorbing) plate made of polymer is used as the outer material (shape maintaining material) of the article, thereby making it possible to prevent the leakage of information stored in accommodated related items, such as an IC card, an RF chip, a smart key, and other IT devices, or to protect the devices.

### Technical Solution

According to an aspect of the present invention, there is provided an electromagnetic wave blocking storage article.

The electromagnetic wave blocking storage article includes a wallet body part configured such that a storage pocket is formed therein, and an electromagnetic shielding part configured to be formed in a plate shape, to be embedded in the wallet body part, and to block electromagnetic waves from the outside of the wallet body part.

It is preferred that the electromagnetic shielding part includes a polymer base material and electromagnetic shielding powder included in the polymer base material.

It is preferred that the electromagnetic shielding powder has multi-layer electromagnetic shielding films formed from the center to the outer layer thereof and is formed by mixing at least two of ferrite, carbon, nickel alloy, and amorphous metal with each other.

In order to improve shielding performance, a metal mesh made of metal may be attached onto the inner surface of an insertion space formed in the wallet body part so that the polymer base material is inserted thereinto.

It is preferred that the polymer base material is attached via release paper attached onto the outer surface of the metal mesh and the location of the polymer base material is fastened.

Furthermore, an electromagnetic wave blocking band having a length may be installed at an edge of the polymer base material.

The electromagnetic wave blocking band is made of a ferromagnet or metal, and is installed to protrude from the outer surface of the polymer base material or to be fitted into an insertion groove formed at the edge of the polymer base material.

Furthermore, the electromagnetic wave blocking band may be installed in the edge of the wallet body part.

The electromagnetic wave blocking band is made of a ferromagnet or metal, and is installed to protrude from the outer surface of the wallet body part or to be inserted into an outer insertion hole formed in the edge of the wallet body part.

The polymer base material may include a plurality of unit polymer base materials formed to be detachable from each other such that the size of the polymer base material is adjustable.

It is preferred that the plurality of unit polymer base materials is coupled to each other in a protrusion-depression fitting manner.

It is preferred that an auxiliary shielding part configured such that a hole having a predetermined size is perforated therein is further installed in the polymer base material.

### Advantageous Effects

According to the present invention, the electromagnetic shielding material made of polymer is used as the outer material (shape maintaining material) of an article, thereby making it possible to prevent the leakage of information stored in accommodated related items, such as an IC card, an RF chip, a smart key, and other IT devices, or to protect the devices.

Furthermore, according to the present invention, the metallic material (including conductive fiber and conductive films), installed inside/outside a wallet body part, and the outer surface of the polymer base material are attached to each other, and thus strength can be increased by a predetermined level or more, electromagnetic waves transferred from the outside can be blocked in multiple stages, and also the range of shielding target frequencies can be selected.

Furthermore, according to the present invention, the plate-shaped electromagnetic shielding part is inserted and fastened to the inside/outside of the wallet body part and, thus, may be easily replaced.

### DESCRIPTION OF DRAWINGS

FIG. 1 is a perspective view showing an electromagnetic wave blocking storage article according to the present invention;

FIG. 2 is a sectional view taken along line A-A of FIG. 1;

FIGS. 3 and 4 are views showing examples of an electromagnetic shielding part according to the present invention;

FIG. 5 is a view showing an example of electromagnetic shielding powder according to the present invention;

FIG. 6 is a view showing another example of the installation of a polymer base material according to the present invention;

FIGS. 7 and 8 are views showing an example in which an electromagnetic wave blocking band is formed on the polymer base material according to the present invention;

FIG. 9 is a view showing an example in which an electromagnetic wave blocking band is formed in the wallet body part according to the present invention; and

FIG. 10 is a view showing an example of a polymer base material the size of which is adjustable according to the present invention.

### MODE FOR INVENTION

An electromagnetic wave blocking storage article having an information protection function and a device protection function according to the present invention will be described below with reference to the accompanying drawings.

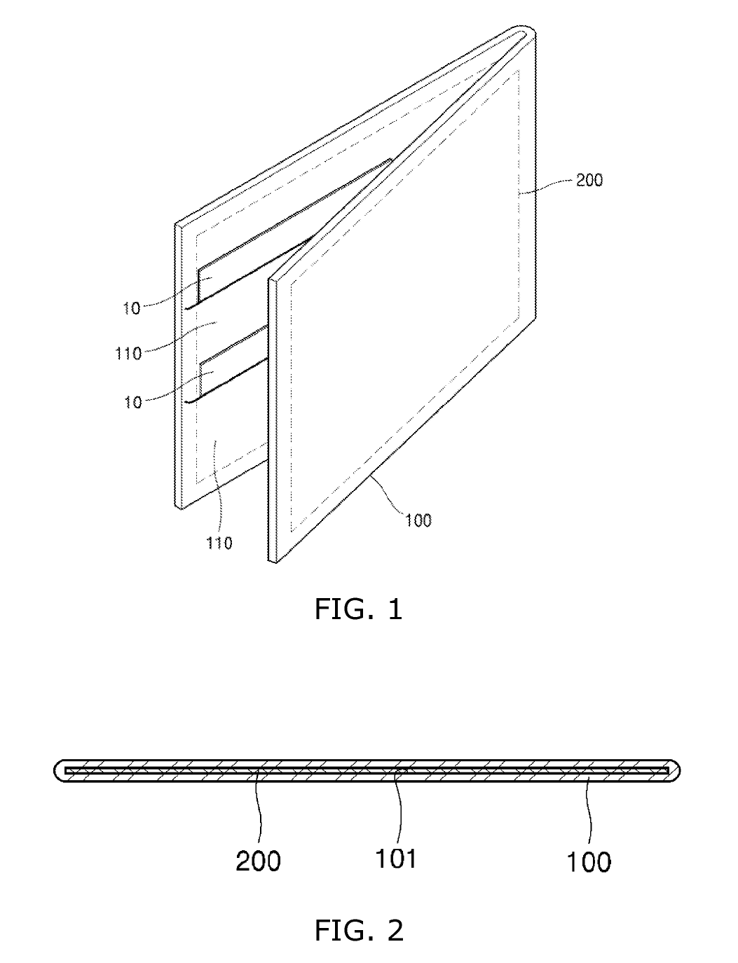

FIG. 1 is a perspective view showing an electromagnetic wave blocking storage article according to the present invention, and FIG. 2 is a sectional view taken along line A-A of FIG. 1.

Referring to FIG. 1, the electromagnetic wave blocking storage article according to the present invention basically includes a wallet body part 100, and an electromagnetic shielding part 200.

The wallet body part 100 has a storage pocket 110.

It is preferred that the wallet body part 100 according to the present invention is a wallet which is foldable around the center thereof.

However, the storage article according to the present invention may be a wallet or small bag openable via a zipper, other than the foldable wallet. In other words, the storage article according to the present invention includes bags which can accommodate stuffs.

In the present specification, the former will be described as a representative example.

The storage pocket 110 in which a card is stored is formed on the inner surface of the wallet body part 100.

The storage pocket 110 is used as a space, an upper end of which is opened and in which a plate-shaped electronic card, such as an IC card, is stored.

The wallet body part 100 may have a predetermined thickness, and may be made of leather or a processed vinyl material having a thickness in order to have flexibility.

An insertion space 101 is formed inside the wallet body part 100.

The electromagnetic shielding part 200 according to the present invention may be inserted into the insertion space 101 and embedded therein.

The electromagnetic shielding part 200 may be formed in a plate shape.

The plate-shaped electromagnetic shielding part 200 is fitted and installed into the insertion space 101.

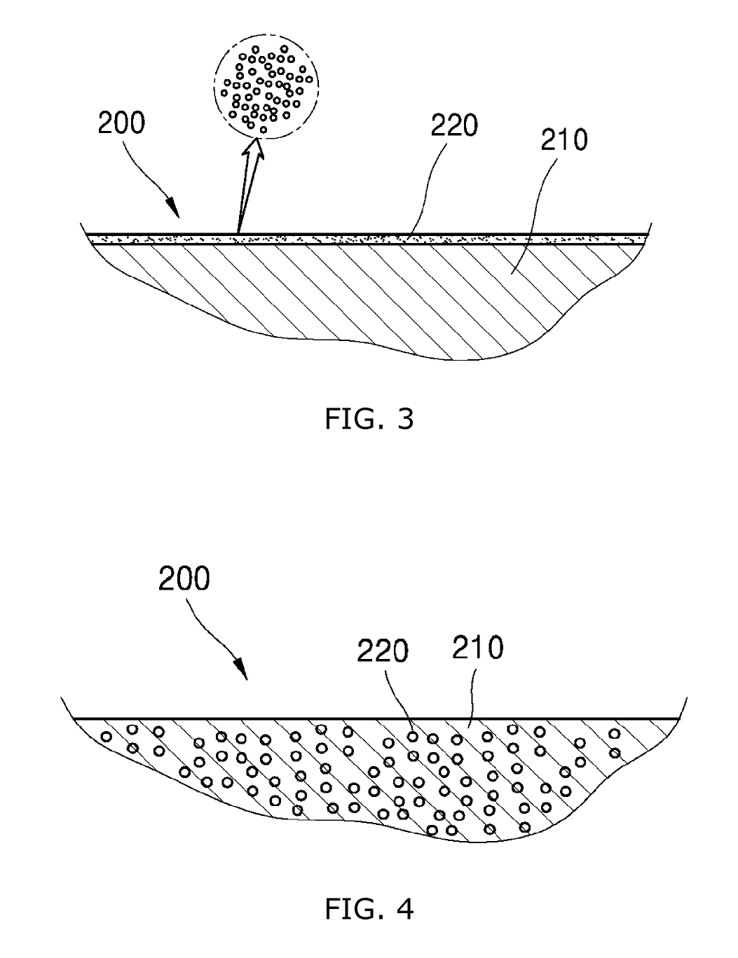

FIGS. 3 and 4 are views showing examples of an electromagnetic shielding part according to the present invention.

Referring to FIG. 3, an electromagnetic shielding part 200 according to the present invention includes a polymer base material 210 and electromagnetic shielding powder 220.

The polymer base material 210 is formed in a plate shape such that the polymer base material 210 may be fitted into the insertion space 101.

Accordingly, the polymer base material 210 may function to maintain the shape of the wallet body part 100 itself.

The electromagnetic shielding powder 220 may be applied on the outer surface of the polymer base material 210, or may be mixed with the polymer base material 210 when the polymer base material 210 is manufactured, as shown in FIG. 4.

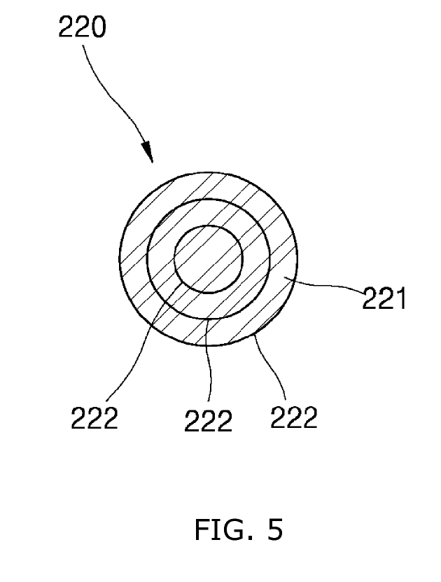

FIG. 5 is a view showing an example of an electromagnetic shielding powder according to the present invention.

Referring to FIG. 5, one or more electromagnetic shielding films 222, the radii of which vary from a center to an outer layer, may be formed in one or more layers in the electromagnetic shielding powder 220.

Furthermore, the electromagnetic shielding powder 220 is formed by mixing 221 at least two of ferrite, carbon, nickel alloy, and amorphous metal with each other.

Accordingly, in the present invention, the polymer base material 210 itself primarily blocks external electromagnetic waves, and the electromagnetic shielding powder 220 itself mixed therein secondarily blocks the external electromagnetic waves, in which case the electromagnetic waves can be additionally blocked in multiple stages by the multi-layer electromagnetic shielding films 222 formed in the powder 220.

The electromagnetic shielding part configured as described above is inserted and installed into the insertion space formed in the wallet body part, and thus a shape maintaining function can be achieved and also electromagnetic waves can be efficiently blocked such that IC cards received in storage pockets are not exposed to external electromagnetic waves.

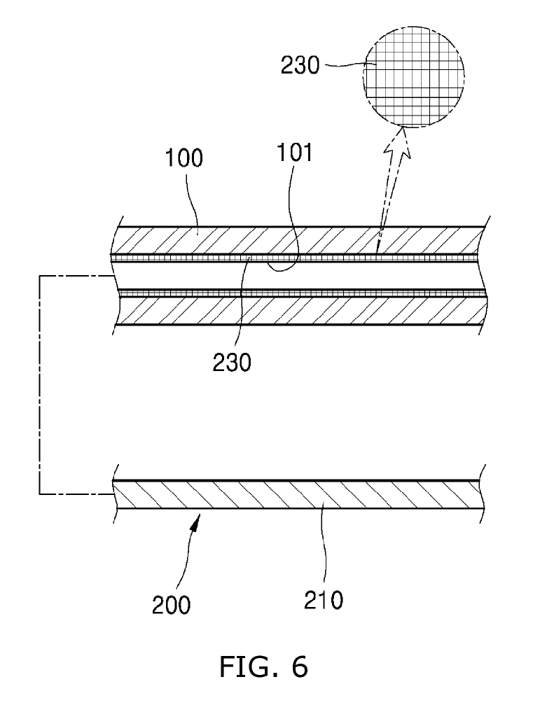

FIG. 6 is a view showing another example of the installation of a polymer base material according to the present invention.

Referring to FIG. 6, a polymer base material according to the present invention may be the same as that described above.

However, a metal mesh (or a conductive fiber) 230 made of metal is further attached and installed onto the inner surface of the insertion space 101 formed in the wallet body part 210 according to the present invention.

In this case, release paper (not shown) is attached to the outer surface of the metal mesh 230.

It will be apparent that conductive adhesive (not shown) for attachment, together with the release paper, may be applied onto the outer surface of the metal mesh in advance.

Accordingly, when the polymer base material 210 according to the present invention is inserted into the insertion space 101, the outer surface of the polymer base material 210 may be attached and fastened via the release paper attached to the outer surface of the metal mesh 230.

Accordingly, as the metal mesh is attached to the outer surface of the polymer base material according to the present invention, an effect is achieved in that another shielding layer which can block electromagnetic waves is formed.

In addition, as described above, when the conductive adhesive, together with the release paper, is applied onto the metal mesh 230 and the polymer base material 210 inserted into the insertion space 101 is attached and fastened therethrough, an advantage is achieved in that another electromagnetic shielding layer, together with the metal mesh 230, is formed.

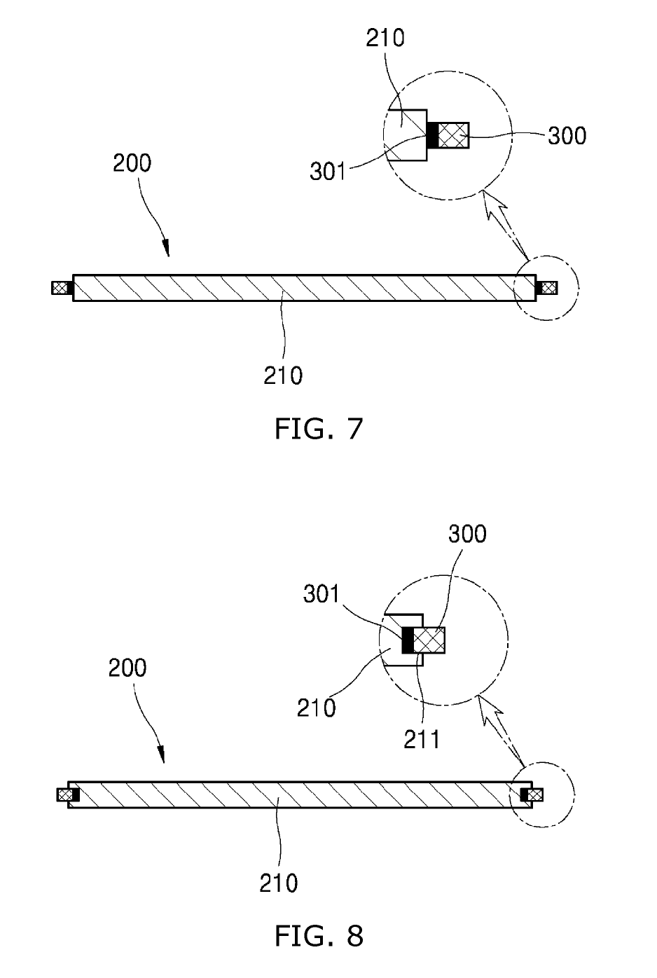

FIGS. 7 and 8 are views showing examples in which an electromagnetic wave blocking band is formed in a polymer base material according to the present invention.

Referring to FIG. 7, an electromagnetic shielding part 200 according to the present invention further includes an electromagnetic wave blocking band 300.

The electromagnetic wave blocking band 300 may be made of a ferromagnet or metal.

The electromagnetic wave blocking band 300 is installed at the edge of the polymer base material 210.

The electromagnetic wave blocking band 300 is installed to protrude from the edge of the polymer base material 210, and is attached and installed on the outer surface of the edge of the polymer base material 210 via separate conductive adhesive 301.

Meanwhile, referring to FIG. 8, a fitting groove 211 may be formed at the edge of the polymer base material 210, and the electromagnetic wave blocking band 300 may be installed such that a portion thereof is fitted into the fitting groove 211.

It will be apparent that it is preferred that the conductive adhesive 301 is applied into the fitting groove 211 in advance.

Accordingly, the present invention has an advantage in that electromagnetic waves transferred through the edge of the wallet body part 100, among electromagnetic waves transferred from the outside of the wallet body part 100, can be blocked via the electromagnetic wave blocking band 300.

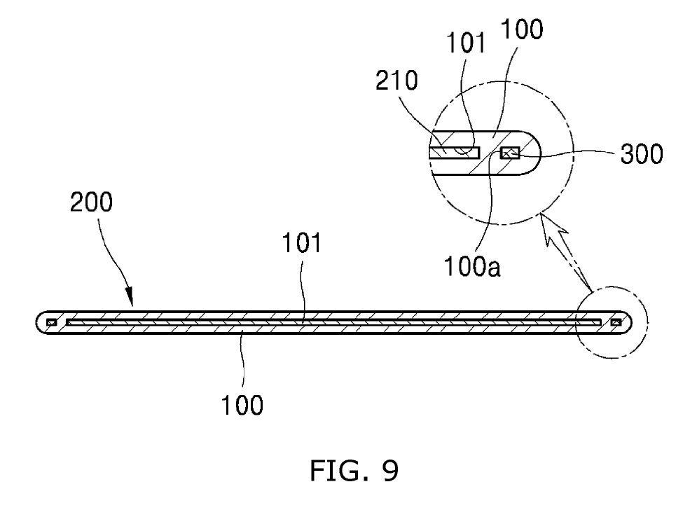

FIG. 9 is a view showing an example in which an electromagnetic wave blocking band is formed in a wallet body part according to the present invention.

Referring to FIG. 9, as described above, an electromagnetic wave blocking band 300 according to the present invention may be made of a ferromagnet or metal.

The electromagnetic wave blocking band 300 formed as described above may be installed in the edge of a wallet body part 100.

It is preferred that the electromagnetic wave blocking band 300 is not exposed to the outside through the edge of the wallet body part 100 and is fitted and fixedly installed in an edge hole 100a formed along the edge of the wallet body part 100.

Accordingly, in the present invention, when the wallet body part is folded around the central boundary thereof so that the storage pockets are protected from the outside, electromagnetic waves generated from the outside and transferred to the edge of the wallet body part may be blocked so as not to be transferred to the storage pockets.

Furthermore, although not shown in the drawing, the configurations of FIGS. 7, 8, and 9 may be formed in a single wallet body part.

In other words, one of the electromagnetic wave blocking bands 300 is embedded in the edge of the wallet body part 100 and the other electromagnetic wave blocking band 300 is installed at the edge of the polymer base material 210, and thus an advantage may be achieved in that electromagnetic waves transferred to the edge of the wallet body part 100 can be blocked in multiple stages.

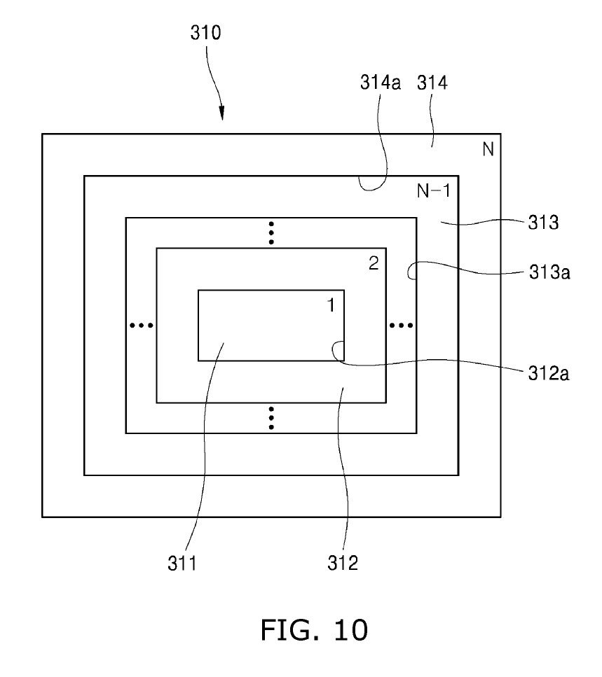

FIG. 10 is a view showing an example of a polymer base material the size of which is adjustable according to the present invention.

Referring to FIG. 10, a polymer base material 310 according to the present invention may include a plurality of unit polymer base materials having different sizes.

The plurality of unit polymer base materials includes a first unit polymer base material 311, a second unit polymer base material 312, . . . , an (N-1)-th unit polymer base material 313, and an N-th unit polymer base material 314.

For example, the (N-1)-th unit polymer base material 313 is fitted into an N-th groove 314a formed in the N-th unit polymer base material 314.

Accordingly, the first unit polymer base material 311 is fitted into a second groove 312a formed in the second unit polymer base material 312.

In this case, a separate groove may not be formed in the first unit polymer base material 311.

Reference symbol 313a designates the (N-1)-th groove of the (N-1)-th unit polymer base material 313.

However, although not shown in the drawing, a hole having a predetermined size may be perforated.

The hole may be formed to have a size varying depending on a blocking frequency when a polymer base material 310 is manufactured.

This configuration may be used to, for example, when it is desired to use a traffic card among IC cards, enable the traffic card to be normally used by blocking frequencies higher than a frequency generated by a traffic card terminal.

In addition, when it is desired to change a desired blocking frequency, another first unit polymer base material with a hole having a different size may be substituted.

Referring to the above-described configurations and effects, in the embodiments according to the present invention, an electromagnetic shielding plate made of polymer may be inserted into the outer material (shape maintaining material) of an article, thereby making it possible to prevent the leakage of information stored in stored related items, such as an IC card, an RF chip, a smart key, etc., or to protect the devices.

Furthermore, in the embodiments according to the present invention, the metal mesh, installed in the wallet body part, and the outer surface of the polymer base material are attached to each other, and thus strength can be increased by a predetermined level or more and also electromagnetic waves transferred from the outside can be blocked in multiple stages.

Furthermore, in the embodiments according to the present invention, the plate-shaped electromagnetic shielding part is inserted and fastened into the wallet body part and, thus, may be easily replaced.

Although the specific embodiments of the electromagnetic wave blocking wallet according to the present invention have been described above, it will be apparent that various modifications may be made without departing from the scope of the present invention.

Therefore, the scope of the present invention should not be limited to the described embodiments, and should be defined based on not only the appended claims but also equivalents thereto.

In other words, it should be understood that the above-described embodiments are not restrictive but illustrative in all aspects, and it should be appreciated that the scope of the present invention is defined by the appended claims rather than the detailed description and all alterations or modifications derived from the meanings and the scope of the appended claims and concepts equivalent thereto are included in the scope of the present invention.

1. An electromagnetic wave blocking storage article having an information protection function, the electromagnetic wave blocking storage article comprising:
a storage body part configured such that a storage pocket is formed therein; and
an electromagnetic shielding part and an electromagnetic absorbing part configured to be formed in plate shapes, to be installed inside/outside the storage body part, and to block electromagnetic waves transferred from an outside of the storage body part.

2. The electromagnetic wave blocking storage article of claim 1, wherein the electromagnetic shielding part comprises,
a polymer base material; and
electromagnetic shielding and absorbing powder included in the polymer base material;
wherein the electromagnetic shielding and absorbing powder:
has multi-layer electromagnetic shielding films formed from a center to an outer layer of the electromagnetic shielding and absorbing powder; and
is formed by mixing at least two of organic/inorganic materials, including ferrite, carbon, nickel alloy, and amorphous metal, with each other.

3. The electromagnetic wave blocking storage article of claim 1, wherein an electromagnetic wave reception part is embedded in the polymer base material to thus become aware that electromagnetic waves are applied from the outside.

4. The electromagnetic wave blocking storage article of claim 2, wherein:
a metallic material (mesh, paper, fiber, or a film) made of metal is attached and installed onto an inner surface of an insertion space formed in the wallet body part so that the polymer base material is inserted; and
one or more surfaces of the polymer base material inserted and embedded in the insertion space are surrounded by the metallic material (mesh, paper, fiber, or a film), and the polymer base material is attached via release paper attached to one surface of the metallic material (mesh, paper, fiber, or a film) so that a location of the polymer base material is fastened.

5. The electromagnetic wave blocking storage article of claim 2, wherein:
an electromagnetic wave blocking band having a length is installed at an edge of the polymer base material; and
the electromagnetic wave blocking band is made of a ferromagnet or metal, and is installed to protrude from an outer surface of the polymer base material or to be fitted into an insertion groove formed at the edge of the polymer base material.

6. The electromagnetic wave blocking storage article of claim 2, wherein:
the polymer base material comprises a plurality of unit polymer base materials formed to be detachable from each other such that a size and thickness of the polymer base material are adjustable; and
the plurality of unit polymer base materials are coupled to each other in a protrusion-depressing fitting manner.

7. The electromagnetic wave blocking storage article of claim 2, wherein an auxiliary shielding part configured such that a hole having a predetermined size is perforated therein is further installed in the polymer base material.
